(19) United States
(12) Patent Application Publication
(10) Pub. No.: US 2025/0031356 A1
(43) Pub. Date: Jan. 23, 2025

(54) HOLDING DEVICE AND HOLDING PROCESS

(71) Applicant: ASMPT GmbH & Co. KG, Munich (DE)

(72) Inventors: Christoph FISCHER, Geretsried (DE); Vincent PFEIFER, Munich (DE)

(21) Appl. No.: 18/775,048

(22) Filed: Jul. 17, 2024

(30) Foreign Application Priority Data
Jul. 20, 2023 (DE) 10 2023 119 169.1

(51) Int. Cl. H05K 13/02

(52) U.S. Cl. CPC H05K 13/021

(57) ABSTRACT

The invention relates to a holding device (10) for holding a plurality of feeder devices (140) for providing electronic components (110) to a pick and place machine, the holding device (10) comprising a basic body (20) with a holding volume (22) for holding the plurality of feeder devices (140) and at least one opening device (40) for opening and closing the holding volume (22), wherein the holding device (10) comprises a detection device (60) and a control device (70), wherein the detection device (60) is designed to detect a transport device (160) separate from the holding device (10) for transporting at least one feeder device (140) and the control device (70) is designed to automatically open and close the opening device (40) on the basis of the detected transport device (160). The invention also relates to a holding process (200).

The present invention relates to a holding device for holding a plurality of feeder devices for providing electronic components to a pick and place machine. Furthermore, the invention relates to a holding process for holding at least one feeder device for providing electronic components to a pick and place machine by means of a holding device.

In the technical field of pick and place technology for electronic components on substrates, for example, there are a large number of different components, for example with resin-sealed housings, which can be damaged by moisture and its expansion inside the component during further processing steps such as a soldering process. These components should preferably be stored in a defined, in particular dry, environment.

Preferably, these components are initially welded airtight before being used for the first time. Drying cabinets are known to be used for the storage of component reels that have already been started, in which the corresponding moisture-sensitive components can be placed by hand.

There is a need in the industry to minimize the manual work required to operate pick and place machines. Known feed devices for the component coils for supplying the components to a pick and place machine are increasingly being replaced by feeder devices with integrated component magazines and/or component coils. No holding device is known for such feeder devices with moisture-sensitive devices.

It is therefore the object of the present invention to eliminate or at least partially eliminate the disadvantages in the prior art described above. In particular, it is the object of the invention to provide a holding device which makes it particularly easy to hold a plurality of feeder devices for providing electronic components to a pick and place machine. Furthermore, it is also the object of the invention to provide a holding process for holding at least one feeder device for providing electronic components to a pick and place machine by means of a holding device.

The object set out above is achieved by the claims. In particular, the object is achieved by a holding device for holding a plurality of feeder devices for providing electronic components to a pick and place machine with the features of independent claim 1. Furthermore, the object is achieved by a holding process for holding at least one feeder device for providing electronic components to a pick and place machine by means of a holding device having the features of independent claim 12. Further advantages and details of the invention emerge from the dependent claims, the description and the drawings. Features and details that are described in connection with the holding device according to the invention naturally also apply in connection with the holding process according to the invention, and vice versa in each case, such that reciprocal reference is or can always be made with respect to the disclosure of individual aspects of the invention.

According to a first aspect of the invention, the object is achieved by a holding device for holding a plurality of feeder devices for providing electronic components to a pick and place machine. The holding device comprising a basic body with a holding volume for holding the plurality of feeder devices and at least one opening device for opening and closing the holding volume, wherein the holding device comprises a detection device and a control device, wherein the detection device is designed for detecting a transport device separate from the holding device for transporting at least one feeder device and the control device is designed for automated opening and airtight closing of the opening device on the basis of the detected transport device.

The holding device is preferably designed to be airtight or essentially airtight. Closing preferably enables an airtight closure of the holding volume.

In the context of the invention, the feeder devices are preferably understood as feeder devices with integrated component magazines, in particular component coils. Alternatively, or additionally, the feeder devices are to be understood as feeder cassettes, tape reels and/or differently designed component storage devices. The electronic components are preferably to be understood as moisture-sensitive devices (MSD). The feeder devices are preferably designed to provide the electronic components to a pick and place machine when used with a pick and place machine.

The holding device is designed to hold a plurality of feeder devices. For example, the feeder device offers a holding option for 10, 20 or 30 feeder devices. The basic body of the holding device is preferably to be understood as a housing, in particular as an airtight or essentially airtight housing. The phrase “X or essentially X” is to be understood in the context of the invention as a possible minor deviation, for example due to manufacturing tolerances, material and/or process properties, without changing the underlying, intended function of the feature. The basic body comprises a holding volume within the basic body. The basic body further comprises at least one opening device, in particular precisely one opening device, for opening and closing the holding volume for inserting and/or removing the feeder devices into and/or from the holding volume. The opening device and/or the basic body preferably have at least one sealing device for airtight closure of the holding volume. The opening device is preferably designed for at least partially automated opening and closing.

The insertion and/or removal of the feeder devices into and/or from the holding volume is preferably carried out by the transport device, which is separate from the holding device. The transport device is designed to transport at least one feeder device, in particular a plurality of feeder devices. Preferably, the transport device is designed as a known transport robot and/or line robot. The transport device is preferably to be understood as an external, independent and/or mobile transport device in relation to the holding device according to the invention.

The holding device is particularly advantageous due to the control device as well as the detection device, because the detection device is designed to detect the transport device and the control device is designed to automatically open and close the opening device based on the detected transport device. The control device is preferably connected to the opening device and/or the detection device in a manner that allows data and/or signal communication. The control device preferably comprises a logic device for evaluating the detection data of the detection device.

A holding device designed in this way is particularly advantageous, as it makes it particularly easy to hold a plurality of feeder devices for providing electronic components to a pick and place machine, with the dehumidification device enabling an advantageous environment for moisture-sensitive components in the holding volume and the opening device, in conjunction with the control device and the detection device, enabling advantageous automated opening and closing of the opening device and advantageous insertion and/or removal of the feeder devices into and/or from the holding volume.

According to a preferred further development of the invention, it can be provided that the holding device comprises a dehumidification device for dehumidifying the air in the holding volume, in particular wherein the dehumidification device comprises a drying device and/or a temperature control device, wherein the drying device is designed to dry the air in the holding volume and/or wherein the temperature control device is designed to control the temperature of the air in the holding volume, in particular wherein the drying device and the temperature control device are of a common design.

The holding device comprises a dehumidification device for dehumidifying the air in the holding volume. The dehumidification device thus preferably enables an advantageous environment in the holding volume for moisture-sensitive devices. The dehumidification device preferably comprises at least one air conveying device, for example a fan and/or a blower, and/or a liquid storage tank for storing liquid from the air of the holding volume. Alternatively, or additionally, the dehumidification device comprises a drain interface for draining liquid from the air of the holding volume. The dehumidification of the air in the holding volume is preferably to be understood as the removal of moisture from the air in the holding volume.

A common design of the drying device and the temperature control device is preferably to be understood as a common housing, as a common design of, for example, a heating device and/or an air conveying device and/or as a common flow channel. The temperature control device is preferably to be understood as a heating device and/or a cooling device. Preferably, the temperature control device and/or the drying device has an exhaust air device and/or supply air device for one-sided and/or two-sided air exchange with the surroundings of the holding device. A holding device designed in this way is particularly advantageous due to the design of the dehumidification device, as it makes it particularly easy to dehumidify the air in the holding volume.

According to a preferred further development of the invention, it may be provided in a holding device that the holding device comprises at least one sensor device for detecting at least one ambient value within the holding volume, in particular wherein the dehumidification device is designed to dehumidify the air in the holding volume on the basis of the at least one detected ambient value. The holding device is preferably designed to control the dehumidification device by means of the at least one sensor device and/or on the basis of the at least one detected ambient value. The sensor device is preferably designed as a measuring device. The sensor device is preferably designed to detect at least one value for humidity, temperature and/or pressure in the holding device, in particular the holding volume. The holding device preferably comprises an operating unit for controlling and/or regulating the dehumidification device, in particular on the basis of the at least one detected ambient value. The holding device preferably comprises an output device for outputting the at least one detected ambient value and/or an adjustable setpoint value for the at least one detected ambient value. A holding device designed in this way is particularly advantageous due to the at least one sensor device for detecting at least one ambient value, as dehumidification of the air in the holding volume is made possible in a particularly simple and/or controlled manner.

According to a preferred further development of the invention, it may be provided in a holding device that the detection device is designed for active and/or passive detection of a transport device separate from the holding device and/or that the detection device comprises a data interface for sending and/or receiving data to and/or from the transport device. The detection device is preferably designed for active and/or passive detection of the transport device. By way of a clear description, the transport device can be detected actively by the detection device, for example optically, and/or passively, for example by an opening request, in particular a data- and/or signal-based opening request, by the transport device to the detection device. The detection device is preferably designed as an IO interface, a data interface and/or a signal interface. The detection device preferably comprises at least one sensor device, in particular an optical sensor device, for detecting the transport device and/or for receiving data and/or signals from the transport device. A holding device designed in this way is particularly advantageous due to the design of the detection device, as it is particularly easy to insert and/or remove the feeder devices into and/or from the holding volume and/or to dehumidify the air in the holding volume.

According to a preferred further development of the invention, it may be provided in a holding device that the holding device comprises a plurality of positioning devices to hold the plurality of feeder devices in position within the holding volume, in particular wherein the plurality of positioning devices comprises a plurality of feeder positions for holding at least one feeder device each. In the context of the invention, the plurality of positioning devices are preferably to be understood as devices for positioning and/or for securing the position of the feeder devices within the holding volume. To put it clearly, the plurality of positioning devices are designed, for example, as spatial boundaries, partitions, webs and/or arrangements to advantageously hold position the plurality of feeder devices in a repeatable manner and/or in a defined position. The positioning devices allow advantageously defined distances between the feeder devices and consequently an advantageous circulation within the holding volume. The positioning devices preferably form a plurality of feeder positions, wherein each feeder position is preferably designed for holding at least one or exactly one feeder device. A holding device designed in this way is particularly advantageous due to the plurality of positioning devices, as it is particularly easy to insert and/or remove the feeder devices into and/or from the holding volume and/or to dehumidify the air in the holding volume.

According to a preferred further development of the invention, it may be provided in a holding device that the holding device comprises a recognition device, wherein the recognition device is designed to recognize at least one feeder device within the holding volume and/or to recognize at least one empty positioning device, in particular wherein the control device is designed to automatically open and close the opening device on the basis of the recognized feeder device within the holding volume and/or the recognized empty positioning device.

The recognition of an empty positioning device and/or at least one feeder device within the holding volume by the recognition device advantageously enables opening and closing of the opening device, which takes into account the recognized empty positioning device and/or the recognized at least one feeder device within the holding volume. For example, the opening device is only opened by the control device in such a way that the recognized at least one feeder device is released for removal by the separate transport device, for example, wherein the smallest possible opening of the holding volume is simultaneously created by the opening device. In other words, the recognition device enables the least possible exchange between the air in the holding volume and the environment by taking into account the position of the recognized at least one feeder device within the holding volume and/or the recognized empty positioning device for the opening of the opening device by the control device. The holding device is preferably designed to recognize a feeder device by the recognition device, for example by reading a feeder ID. This is done, for example, by switching on or a switch-on process of the feeder device, via a standard interface between the feeder device and the holding device and/or via an RFID tag in and/or on the feeder device. Additionally, or alternatively, the holding device is preferably designed to communicate with the corresponding transport device, so that data about a feeder device to be delivered can be processed and taken into account, for example, when selecting a positioning device for the corresponding feeder device. The request to open the opening device is preferably active or passive. In other words, the request to open the opening device is made by the holding device, the feeder device, the transport device and/or via a higher-level logic system, wherein the corresponding logic system is preferably connected to the holding device, the feeder device and/or the transport device in a manner that allows data communication. A holding device designed in this way is particularly advantageous due to the design of the recognition device, as it is particularly easy to insert and/or remove the feeder devices into and/or from the holding volume and/or to dehumidify the air in the holding volume and an exchange of air is advantageously minimized when opening the opening device.

According to a preferred further development of the invention, a holding device can be provided with at least one opening device for the defined, section-by-section opening of the holding volume, in particular for a defined minimum opening of at least one feeder position, and/or wherein the opening device is designed in at least two parts and/or as a lateral roller shutter. When the holding volume is opened, air can always be exchanged between the holding volume and the environment, which has a negative effect on the favorable environment within the holding volume. An advantageous further development is therefore provided if the holding volume is opened in such a way that the exchange of air between the holding volume and the environment is kept to a minimum. By way of a clear description, it is advantageous if only a defined opening, sectional opening and/or minimum opening of the opening device takes place, thus enabling the removal and/or insertion of at least one feeder device, in particular only one feeder device, from the holding volume and/or into the holding volume. The opening device is preferably designed as an opening device for opening exactly one feeder position. The opening device is preferably designed as a lateral roller shutter, sliding door, roller shutter and/or at least in two parts. It is particularly preferable if the opening device is designed as a lateral roller shutter with at least two roller shutter halves, in particular with each roller shutter half having a width that corresponds to at least 80%, preferably at least 90% or at least 95% of a width of the opening device and/or the holding volume. An opening device designed in this way is particularly advantageous, as the two roller shutter halves are designed to move together and allow an opening slot in front of each and/or in front of exactly one feeder device. A holding device designed in this way is particularly advantageous due to the design of the opening device, as it is particularly easy to insert and/or remove the feeder devices into and/or from the holding volume and/or to dehumidify the air in the holding volume and an exchange of air is advantageously minimized when opening the opening device.

According to a preferred further development of the invention, it may be provided in a holding device that the holding device, in particular the plurality of positioning devices, comprises a plurality of guide devices in the holding volume, wherein the plurality of guide devices are each designed for guiding and/or for detachably coupling at least one of the plurality of feeder devices. A guide and/or detachable coupling of the plurality of feeder devices within the holding volume is particularly advantageous in order to enable a safe and repeatable arrangement and/or securing of the position of the plurality of feeder devices within the holding volume. The guide devices are preferably designed as guide rails, in particular as an omega profile, as guide slots, at least in two parts and/or on opposite sides of the holding volume. Guiding the plurality of feeder devices within the holding volume makes it possible to advantageously compensate for inaccuracies in the arrangement between the transport device and the holding device. A detachable coupling is preferably detachable for the removal of a feeder device by the holding device and/or the transport device. The coupling is clearly described, for example, as being formed by a snap-in connection and/or a projection. A holding device designed in this way is particularly advantageous due to the plurality of positioning devices, as it is particularly easy to insert and/or remove the feeder devices into and/or from the holding volume and/or to dehumidify the air in the holding volume.

According to a preferred further development of the invention, a holding device may comprise a coupling device for coupling the separate transport device to a counter-coupling device to secure its position. For insertion and/or removal of the feeder devices into and/or from the holding volume, in particular by the transport device, it is particularly advantageous if the transport device and the holding device are arranged and/or positioned in a defined manner relative to one another. For this defined arrangement relative to one another, the holding device has a coupling device for coupling the separate transport device to a counter-coupling device to secure its position. By way of a clear description, the coupling device enables a coupling with the counter-coupling device of the separate transport device and thus ensures a defined arrangement of the transport device to the holding device with a repeatable accuracy. The coupling device is preferably arranged on an outer side of the holding device in order to provide advantageous accessibility for coupling with the counter-coupling device. For example, the coupling device is designed as a funnel and is designed for coupling with a spherical counter-coupling device, so that the spherical counter-coupling device is guided within the funnel for coupling and, as the counter-coupling device and the coupling device come closer together, enables the transport device to be arranged in a defined manner with respect to the holding device. A holding device designed in this way is particularly advantageous due to the coupling device, as it is particularly easy to insert and/or remove the feeder devices into and/or from the holding volume and/or to dehumidify the air in the holding volume.

According to a preferred further development of the invention, it may be provided in a holding device that the holding device comprises a pressure device, wherein the pressure device is designed to generate an overpressure in the holding volume, in particular wherein the pressure device is designed together with the dehumidification device. The pressure device is an advantageous supplement for the holding device according to the invention, since an overpressure within the holding device, in particular within the holding volume, advantageously reduces or even prevents the ingress of air from the surroundings, in particular when the opening device is opened and/or when the opening device is open. Furthermore, the pressure device is advantageous for reducing or preventing the ingress of air from the surroundings through possible leaks in the basic body of the holding device. The pressure device preferably comprises a pump device for generating the overpressure in the holding volume. A holding device designed in this way is particularly advantageous due to the pressure device, as it is particularly easy to insert and/or remove the feeder devices into and/or from the holding volume and/or to dehumidify the air in the holding volume.

According to a preferred further development of the invention, it may be provided in a holding device that the holding device comprises an identification device, wherein the identification device is configured to identify an ID element of at least one of the plurality of feeder devices. It is particularly advantageous to identify the feeder devices so that the correct feeder devices and thus the correct components can always be removed from the holding device by the transport device. The identification device thus advantageously enables a traceable assignment of the feeder devices within the holding device and/or for the transport device. The data detected from the identification of the ID element is preferably stored on a storage device of the holding device or transmitted to, for example, a separate server device and/or a separate storage device using a data interface of the holding device. The ID element is designed, for example, as a QR code and/or barcode on a feeder device. The holding device is preferably designed to recognize a feeder device by the recognition device, for example by reading a feeder ID. This is done, for example, by switching on or a switch-on process of the feeder device, via a standard interface between the feeder device and the holding device or via an RFID tag in and/or on the feeder device. A holding device designed in this way is particularly advantageous due to identification device, as it makes it particularly easy to traceably insert and/or remove the feeder devices into and/or from the holding volume and/or to dehumidify the air in the holding volume.

According to a second aspect of the invention, the object is achieved by a holding process for holding at least one feeder device for providing electronic components to a pick and place machine by means of a holding device. The holding process comprises:
Detection of a transport device separate from the holding device for transporting at least one feeder device by a detection device of the holding device,
Opening and/or closing of the holding volume by an opening device of the holding device by means of a control device of the holding device on the basis of the detected transport device.

Unless explicitly stated otherwise, the method steps described above and below can be carried out individually, together, once, multiple times, at the same time and/or one after the other in any order. A designation as, for example, “first procedural step” and “second procedural step” does not require any chronological order and/or prioritization. A preferred order of the method steps provides that the method steps are carried out in the order listed. The dehumidification of the air in the holding volume preferably takes place constantly or depending on the condition, in particular in a controlled manner and/or depending on an ambient value detected by a sensor device of the holding device. A holding process designed in this way is particularly advantageous, as it makes it particularly easy to hold a plurality of feeder devices for providing electronic components to a pick and place machine, with the dehumidification device enabling an advantageous environment for moisture-sensitive components in the holding volume and the opening device, in conjunction with the control device and the detection device, enabling advantageous automated opening and closing of the opening device and advantageous insertion and/or removal of the feeder devices into and/or from the holding volume.

According to a preferred further development of the invention, in a holding process it may be provided that the holding device is designed according to the first aspect. All the advantages that have already been described for the holding device according to the first aspect of the invention result from the described holding process.

According to a preferred further development of the invention, in a holding process it may be provided that the holding process, in particular the opening and/or closing, further comprises:
A defined minimum opening of the opening device for at least one feeder device, in particular exactly one feeder device and/or
Dehumidifying the air in a holding volume of a basic body of the holding device.

When the holding volume is opened, air can always be exchanged between the holding volume and the environment, which has a negative effect on the favorable environment within the holding volume. An advantageous further development is therefore provided if the holding volume is opened in such a way that the exchange of air between the holding volume and the environment is kept to a minimum. By way of a clear description, it is advantageous if only a defined opening, sectional opening and/or minimum opening of the opening device takes place, thus enabling the removal and/or insertion of at least one feeder device, in particular only one feeder device, from the holding volume and/or into the holding volume. The opening device is preferably designed as an opening device for opening exactly one feeder position. A holding process designed in this way is particularly advantageous, as it is particularly easy to insert and/or remove the feeder devices into and/or from the holding volume and/or to dehumidify the air in the holding volume and an exchange of air is advantageously minimized when opening the opening device.

A holding device according to the invention and a holding process are explained in more detail below on the basis of drawings. They show schematically in each case:

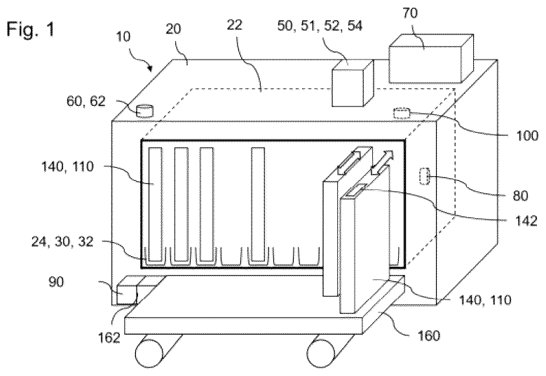

FIG. 1 a perspective view of a holding device for holding a plurality of feeder devices for supplying electronic components to a pick and place machine,

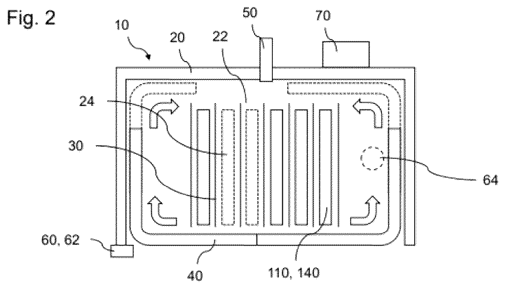

FIG. 2 a top view of a holding device for holding a plurality of feeder devices for supplying electronic components to a pick and place machine,

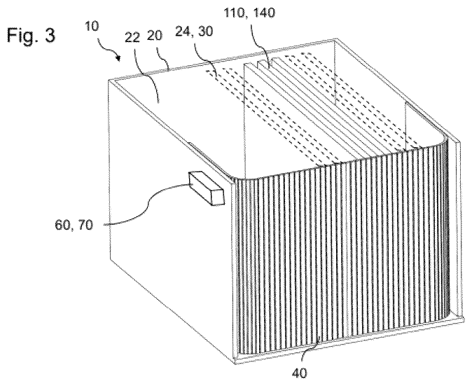

FIG. 3 a perspective view of a further holding device for holding a plurality of feeder devices for supplying electronic components to a pick and place machine,

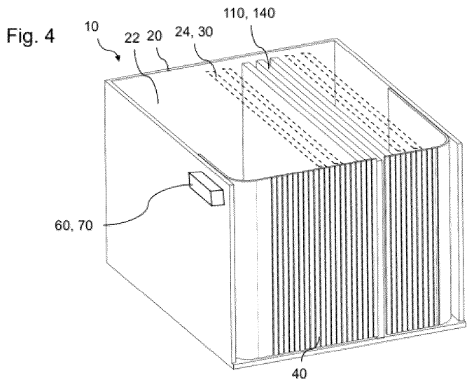

FIG. 4 a perspective view of the holding device from FIG. 3 for holding a plurality of feeder devices for supplying electronic components to a pick and place machine,

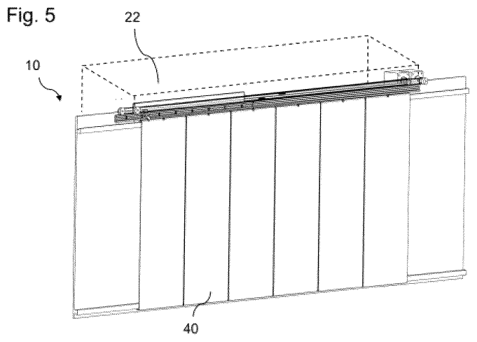

FIG. 5 a perspective view of a further embodiment of the opening device for opening and closing the holding volume,

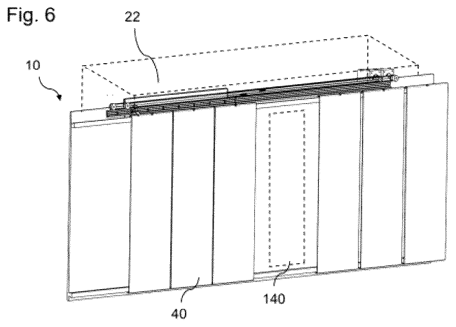

FIG. 6 a perspective view of the configuration of the opening device from FIG. 5 for opening and closing the holding volume, and

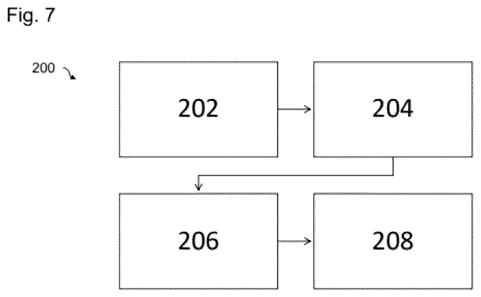

FIG. 7 a holding process in a flowchart.

Elements with the same function and mode of operation are each provided with the same reference signs in FIGS. 1 to 7.

FIG. 1 schematically shows a perspective view of a holding device 10 for holding a plurality of feeder devices 140 for supplying electronic components 110 to a pick and place machine. The holding device 10 comprises a basic body 20 with a holding volume 22 for holding the plurality of feeder devices 140, an opening device 40 (not shown) for opening and closing the holding volume 22, and a dehumidification device 50 for dehumidifying the air in the holding volume 22. For reasons of clarity, the opening device 40 is not shown in FIG. 1. The holding device 10 further comprises a detection device 60 and a control device 70, wherein the detection device 60 is designed to detect a transport device 160 separate from the holding device 10 for transporting a plurality of feeder devices 140 and the control device 70 is designed to automatically open and close the opening device 40 (not shown) on the basis of the detected transport device 160. The dehumidification device 50 comprises a drying device 51 and a temperature control device 52, wherein the drying device 51 is designed to dry the air in the holding volume 22 and/or wherein the temperature control device 52 is designed to control the temperature of the air in the holding volume 22, wherein the drying device 51 and the temperature control device 52 are of a common design. The holding device 10 comprises a sensor device 80 for detecting a plurality of ambient values within the holding volume 22, wherein the dehumidification device 50 is designed to dehumidify the air in the holding volume 22 on the basis of the detected ambient values. The detection device 60 is designed for active and passive detection of a transport device 160 separate from the holding device 10 and the detection device 60 comprises a data interface 62 for transmitting and receiving data to and from the transport device 160. The holding device 10 comprises a plurality of positioning devices 30 to hold the plurality of feeder devices 140 in position within the holding volume 22, wherein the plurality of positioning devices 30 comprises a plurality of feeder positions 24 for holding one feeder device 140 at a time. The holding device 10, here the plurality of positioning devices 30, comprises a plurality of guide devices 32 in the holding volume 22, wherein the plurality of guide devices 32 are each designed for guiding and detachably coupling one of the plurality of feeder devices 140. The holding device 10 comprises a coupling device 90 for coupling the separate transport device 160 to a counter-coupling device 162 to secure its position. The holding device 10 comprises an identification device 100, wherein the identification device 100 is configured to identify an ID element 142 of one of the plurality of feeder devices 140.

FIG. 2 schematically shows a top view of a holding device 10 for holding a plurality of feeder devices 140 for supplying electronic components 110 to a pick and place machine. The holding device 10 comprises a basic body 20 with a holding volume 22 for holding the plurality of feeder devices 140, a two-part opening device 40 for opening and closing the holding volume 22, and a dehumidification device 50 for dehumidifying the air in the holding volume 22. The holding device 10 further comprises a detection device 60 and a control device 70, wherein the detection device 60 is designed to detect a transport device 160 (not shown) separate from the holding device 10 for transporting at least one feeder device 140 and the control device 70 is designed to automatically open and close the opening device 40 on the basis of the detected transport device 160 (not shown). For reasons of clarity, the transport device 160 is not shown in FIG. 2. The holding device 10 comprises a plurality of positioning devices 30 to hold the plurality of feeder devices 140 in position within the holding volume 22, wherein the plurality of positioning devices 30 comprises a plurality of feeder positions 24 for holding one feeder device 140 at a time. The opening device 40 is designed for the defined, section-by-section opening of the holding volume 22, in this case for the defined minimum opening of exactly one feeder position 24. Furthermore, the opening device 40 is in two parts and is designed as a lateral roller shutter. The holding device 10 comprises a recognition device 64, wherein the recognition device 64 is designed to recognize one feeder device 140 within the holding volume 22 and to recognize one empty positioning device 30, wherein the control device 70 is designed to automatically open and close the opening device 40 on the basis of the recognized feeder device 140 within the holding volume 22 and the recognized empty positioning device 30.

FIG. 3 schematically shows a perspective view of a further holding device 10 for holding a plurality of feeder devices 140 for supplying electronic components 110 to a pick and place machine. The holding device 10 comprises a basic body 20 with a holding volume 22 for holding the plurality of feeder devices 140 and a two-part opening device 40 for opening and closing the holding volume 22. The holding device 10 further comprises a detection device 60 and a control device 70, which are of a common design. The opening device 40 is in two parts and is designed as a lateral, articulated roller shutter. The opening device 40 is shown closed in FIG. 3. The holding device 10 comprises a plurality of positioning devices 30 to hold the plurality of feeder devices 140 in position within the holding volume 22, wherein the plurality of positioning devices 30 comprises a plurality of feeder positions 24 for holding one feeder device 140 at a time. In FIG. 3, the holding device 10 is shown cut or open at the top for better illustration.

FIG. 4 schematically shows a perspective view of the holding device 10 from FIG. 3 for holding a plurality of feeder devices 140 for supplying electronic components 110 to a pick and place machine. The holding device 10 comprises a basic body 20 with a holding volume 22 for holding the plurality of feeder devices 140 and a two-part opening device 40 for opening and closing the holding volume 22. The holding device 10 further comprises a detection device 60 and a control device 70, which are of a common design. The opening device 40 is in two parts and is designed as a lateral, articulated roller shutter. In FIG. 4, the opening device 40 is shown open in such a way that exactly one feeder device 140 is released for removal by the separate transport device 160 (not shown), advantageously enabling as little exchange of air as possible between the holding volume 22 and the environment. The holding device 10 comprises a plurality of positioning devices 30 to hold the plurality of feeder devices 140 in position within the holding volume 22, wherein the plurality of positioning devices 30 comprises a plurality of feeder positions 24 for holding one feeder device 140 at a time. In FIG. 4, the holding device 10 is shown cut or open at the top for better illustration.

FIG. 5 schematically shows a perspective view of a further embodiment of the opening device 40 for opening and closing the holding volume 22. The opening device 40 is in six parts and is designed as a lateral roller shutter. The opening device 40 is shown closed in FIG. 5. The individual elements of the roller shutter can preferably be moved independently of one another, so that an opening for at least one feeder device 140 (not shown) can be created between each pair of two adjacent elements of the roller shutter.

FIG. 6 schematically shows a perspective view of an embodiment of the opening device 40 from FIG. 5 for opening and closing the holding volume 22. The opening device 40 is in six parts and is designed as a lateral roller shutter. In FIG. 6, the opening device 40 is shown open in such a way that exactly one feeder device 140 is released for removal by the separate transport device 160 (not shown), advantageously enabling as little exchange of air as possible between the holding volume 22 and the environment. The individual elements of the roller shutter can preferably be moved independently of one another, so that an opening for at least one feeder device 140 can be created between each pair of two adjacent elements of the roller shutter.

FIG. 7 shows a schematic flow diagram of an embodiment of the holding process 200 according to the invention. For improved clarity, only the reference numbers of the method steps are indicated in FIG. 3. In a first process step, the holding process 200 comprises dehumidifying 202 the air in a holding volume 22 of a basic body 20 of the holding device 10. In a further process step, the holding process 200 comprises detection 204 of a transport device 160 separate from the holding device 10 for transporting at least one feeder device 140 by a detection device 60 of the holding device 10. In a further process step, the holding process 200 comprises opening and/or closing 206 of the holding volume 22 by an opening device 40 of the holding device 40 by means of a control device 70 of the holding device 40 on the basis of the detected transport device 160. In a further process step, the holding process 200 comprises the defined minimum opening 208 of the opening device 40 for exactly one feeder device 140.

### LIST OF REFERENCE SIGNS

10 Holding device
20 Basic body
22 Holding volume
24 Feeder positions
30 Positioning devices
32 Guide devices
40 Opening device
50 Dehumidification device
51 Drying device
52 Temperature control device
54 Pressure device
60 Detection device
62 Data interface
64 Recognition device
70 Control device
80 Sensor device
90 Coupling device
100 Identification device
110 Electronic components
140 Feeder device
142 ID element
160 Transport device
162 Counter-coupling device
200 Holding process
202 Dehumidification
204 Detection
206 Opening and/or closing
208 Defined minimum opening

1. A holding device for holding a plurality of feeder devices for providing electronic components to a pick and place machine, the holding device comprising a basic body with a holding volume for holding the plurality of feeder devices and at least one opening device for opening and closing the holding volume,
wherein,
the holding device comprises a detection device and a control device, wherein the detection device is designed to detect a transport device separate from the holding device for transporting at least one feeder device and the control device is designed to automatically open and close the opening device on the basis of the detected transport device.

2. The holding device according to claim 1,
wherein,
the holding device comprises a dehumidification device for dehumidifying the air in the holding volume, in particular wherein the dehumidification device comprises a drying device and/or a temperature control device, wherein the drying device is designed to dry the air in the holding volume and/or wherein the temperature control device is designed to control the temperature of the air in the holding volume, in particular wherein the drying device and the temperature control device are of a common design.

3. The holding device according to claim 1,
wherein,
the holding device comprises at least one sensor device for detecting at least one ambient value within the holding volume, in particular wherein the dehumidification device is designed to dehumidify the air in the holding volume on the basis of the at least one detected ambient value.

4. The holding device according to claim 1,
wherein,
the detection device is designed for active and/or passive detection of a transport device separate from the holding device and/or the detection device comprises a data interface for transmitting and/or receiving data to and/or from the transport device.

5. The holding device according to claim 1,
wherein,
the holding device comprises a plurality of positioning devices to hold the plurality of feeder devices in position within the holding volume, in particular wherein the plurality of positioning devices comprises a plurality of feeder positions for holding at least one feeder device at a time.

6. The holding device according to claim 1,
wherein,
the holding device comprises a recognition device, wherein the recognition device is designed to recognize at least one feeder device within the holding volume and/or to recognize at least one empty positioning device, in particular wherein the control device is designed to automatically open and close the opening device on the basis of the recognized feeder device within the holding volume and/or the recognized empty positioning device.

7. The holding device according to claim 1,
wherein,
the at least one opening device is designed for the defined, section-by-section opening of the holding volume, in particular for the defined minimum opening of at least one feeder position, and/or
wherein the opening device is designed in at least two parts and/or as a lateral roller shutter.

8. The holding device according to claim 1,
wherein,
the holding device, in particular the plurality of positioning devices, comprises a plurality of guide devices in the holding volume, wherein the plurality of guide devices are each designed for guiding and/or detachably coupling at least one of the plurality of feeder devices.

9. The holding device according to claim 1,
wherein,
the holding device comprises a coupling device for coupling the separate transport device to a counter-coupling device to secure its position.

10. The holding device according to claim 1,
wherein,
the holding device comprises a pressure device, wherein the pressure device is designed to generate an overpressure in the holding volume, in particular wherein the pressure device is designed together with the dehumidification device.

11. The holding device according to claim 1,
wherein,
the holding device comprises an identification device, wherein the identification device is configured to identify an ID element of at least one of the plurality of feeder devices.

12. A holding process for holding at least one feeder device for providing electronic components to a pick and place machine by a holding device, the holding process comprising:
Detection of a transport device separate from the holding device for transporting at least one feeder device by a detection device of the holding device,
Opening and/or closing of the holding volume by an opening device of the holding device by means of a control device of the holding device on the basis of the detected transport device.

13. The holding process according to claim 12,
wherein,
the holding device comprises a basic body with a holding volume for holding the plurality of feeder devices and at least one opening device for opening and closing the holding volume, the holding device comprises a detection device and a control device, wherein the detection device is designed to detect a transport device separate from the holding device for transporting at least one feeder device and the control device is designed to automatically open and close the opening device on the basis of the detected transport device.

14. The holding process according to claim 12,
wherein,
the holding process, in particular the opening and/or closing, further comprises:
A defined minimum opening of the opening device for at least one feeder device, in particular exactly one feeder device and/or
Dehumidifying the air in a holding volume of a basic body of the holding device.
